(19) United States
(12) Patent Application Publication
(10) Pub. No.: US 2026/0173795 A1
(43) Pub. Date: Jun. 18, 2026

(54) SUBSTRATE PROCESSING APPARATUS

(71) Applicant: SCREEN Holdings Co., Ltd., Kyoto (JP)

(72) Inventors: Atsushi KUROEDA, Kyoto-shi (JP); Nobuhiko NISHIDE, Kyoto-shi (JP); Hajime NISHIDE, Kyoto-shi (JP); Tomohiro UENO, Kyoto-shi (JP)

(21) Appl. No.: 19/420,485

(22) Filed: Dec. 15, 2025

(30) Foreign Application Priority Data
Dec. 18, 2024 (JP) 2024-221493

(51) Int. Cl. H10P 72/00

(52) U.S. Cl. CPC H10P 72/0461; H10P 72/0402; H10P 72/0456

(57) ABSTRACT

A substrate processing apparatus includes a plurality of dry processing modules, a wet processing module, and a main transporter. The dry processing module includes a load lock unit switching an atmospheric pressure state and a vacuum state, a dry processing unit performing dry processing on a substrate in a vacuum state, and a local transporter transporting a substrate between the load lock unit and the dry processing unit in a vacuum state. The wet processing module performs wet processing on the substrate. The main transporter transports the substrate into and out of the load lock unit in an atmospheric pressure state, and transports the substrate between the dry processing module and the wet processing module.

### BACKGROUND

### Technical Field

The present disclosure relates to a substrate processing apparatus.

### Description of the Background Art

Conventionally proposed is a substrate processing apparatus processing a substrate (for example, Japanese Patent Application Laid-Open No. 2022-18359). In Japanese Patent Application Laid-Open No. 2022-18359, the substrate processing apparatus includes a plurality of processing module and a transfer robot. The transfer robot transports a substrate to each processing module. Each processing module includes a wet processing unit, a dry processing unit, and a transfer unit. The wet processing unit performs wet processing on the substrate. The dry processing unit performs dry processing on the substrate. The transfer unit transports the substrate between the wet processing unit and the dry processing unit.

### SUMMARY

In one aspect, a substrate processing apparatus includes: a plurality of dry processing modules each including a load lock unit switching an atmospheric pressure state and a vacuum state, at least one dry processing unit performing dry processing on a substrate in a vacuum state, and a local transporter transporting a substrate between the load lock unit and the dry processing unit in a vacuum state; at least one wet processing module performing wet processing on the substrate; and a main transporter transporting the substrate into and out of the load lock unit in an atmospheric pressure state and transporting a substrate between each of the dry processing module and the wet processing module.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example of a configuration of a substrate processing apparatus.

FIG. 2 is a vertical cross-sectional view schematically illustrating an example of a specific configuration of a dry processing module.

FIG. 3 is a vertical cross-sectional view schematically illustrating an example of a configuration of a wet processing module.

FIG. 4 is a diagram schematically illustrating an example of an inner configuration of a controller.

FIG. 5 is a diagram schematically illustrating an example of a transportation configuration of the dry processing module.

### DESCRIPTION OF THE EMBODIMENTS

There is a case in Japanese Patent Application Laid-Open No. 2022-18359 where when a processing time is long in any one of the dry processing unit and the wet processing unit, the substrate stands by in the other one of the units in some cases. Thus, there is room for ingenuity in improvement of throughput.

Accordingly, an object of the present disclosure is to provide a substrate processing apparatus capable of improving throughput.

Embodiments are described hereinafter in detail with reference to the diagrams. It should be noted that dimensions of components and the number of components are illustrated in exaggeration or in simplified form, as appropriate, in the diagrams for the sake of easier understanding. The same reference numerals are assigned to parts having a similar configuration and function, and the repetitive description is omitted in the description hereinafter.

In the description hereinafter, the same reference numerals will be assigned to the similar constituent elements in the diagrams, and the constituent elements having the same reference numeral have the same name and function. Accordingly, the detailed description on them may be omitted to avoid a repetition in some cases.

In the following description, even when ordinal numbers such as “first” or “second” are stated, these terms are used to facilitate understanding of contents of embodiments for convenience, and therefore, the usage of the ordinal numbers does not limit the indication of the ordinal numbers to ordering.

Unless otherwise noted, the expressions indicating relative or absolute positional relationships (e.g., “in one direction”, “along one direction”, “parallel”, “orthogonal”, “central”, “concentric”, and “coaxial”) include not only those exactly indicating the positional relationships but also those where an angle or a distance is relatively changed within tolerance or to the extent that similar functions can be obtained. Unless otherwise noted, the expressions indicating equality (e.g., “same”, “equal”, and “uniform”) include not only those indicating quantitatively exact equality but also those in the presence of a difference within tolerance or to the extent that similar functions can be obtained. Unless otherwise noted, the expressions indicating shapes (e.g., “rectangular” or “cylindrical”) include not only those indicating geometrically exact shapes but also those indicating, for example, roughness or a chamfer to the extent that similar effects can be obtained. An expression “comprising”, “with”, “provided with”, “including”, or “having” a certain constituent element is not an exclusive expression for excluding the presence of the other constituent elements. An expression “at least one of A, B, and C” involves only A, only B, only C, arbitrary two of A, B, and C, and all of A, B, and C.

### Whole Configuration of Substrate Processing Apparatus

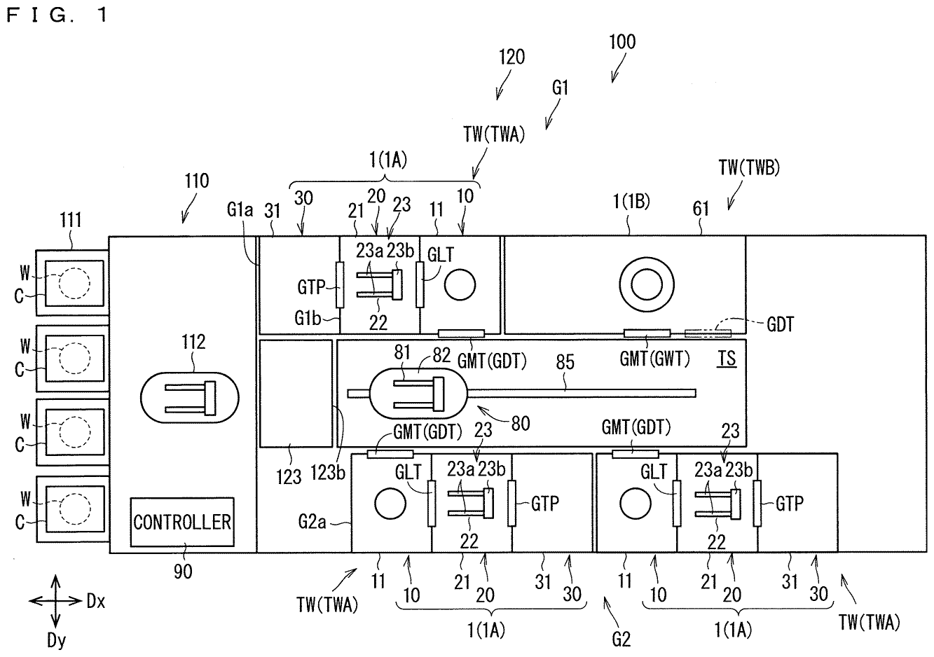

FIG. 1 is a plan view schematically illustrating an example of a configuration of a substrate processing apparatus 100. The substrate processing apparatus 100 is a sheet-like processing apparatus processing a substate W one by one.

The substrate W is a semiconductor wafer, a liquid crystal display apparatus substrate, an electroluminescence (EL) substrate, a flat panel display (FPD) substate, an optical display substrate, a magnetic disk substrate, an optical disk substrate, a magnetic optical disk substrate, a photomask substrate, or a solar cell substrate, for example. The substate W has a thin plate-like shape. In the description hereinafter, the substate W is a semiconductor wafer. The substrate W is a silicon substrate as an example. The substate W is a disk-like shape, for example. A diameter of the substate W is approximately 300 mm, for example, and a thickness of the substate W is approximately equal to or larger than 0.5 mm and approximately equal to or smaller than 3 mm, for example.

In the example in FIG. 1, the substrate processing apparatus 100 includes an indexer block 110, a processing block 120, and a controller 90. The processing block 120 is a part mainly performing processing on the substate W, and the indexer block 110 is a part mainly transporting the substate W between an outer part of the substrate processing apparatus 100 and the processing block 120.

The indexer block 110 includes a load port 111 and an indexer transporter 112. A substrate housing container (referred to as a carrier hereinafter) C is disposed on the load port 111. The plurality of substrates W are housed in the carrier C while being arranged at intervals in a vertical direction, for example. In the example in FIG. 1, the plurality of load ports 111 are arranged.

The indexer transporter 112 is a transfer robot and can take out the unprocessed substrate W from the carrier C disposed on each load port 111. The indexer transporter 112 can also be referred to as an indexer robot. The indexer transporter 112 transports the unprocessed substrate W taken out from the carrier C to the processing block 120. The processing block 120 can perform processing on the unprocessed substate W. The indexer transporter 112 receives the substrate W which has been processed from the processing block 120, and transports the substate W which has been processed to the carrier C of the load port 111.

In the example in FIG. 1, the processing block 120 includes a plurality of processing modules 1 and a main transporter 80. The main transporter 80 is a transfer robot, and can transport the substrate W between the indexer transporter 112 and the plurality of processing modules 1.

As exemplified in FIG. 1, the processing block 120 may also include a transfer part 123. The transfer part 123 relays the substrate W between the indexer transporter 112 and the main transporter 80. The transfer part 123 is also deemed as a relay part. For example, the transfer part 123 includes a shelf on which the plurality of substrates W can be disposed to be arranged in a vertical direction, for example. The transfer part 123 is also deemed as a mounting part where the substrate W is disposed. The indexer transporter 112 places the unprocessed substrate W on the transfer part 123. The main transporter 80 takes out the unprocessed substrate W from the transfer part 123, and transports the unprocessed substrate W to the processing module 1. The processing module 1 performs processing on the substate W.

The plurality of processing modules 1 include a dry processing module 1A and a wet processing module 1B as described hereinafter. The main transporter 80 can also transport the substrate W from one of the dry processing module 1A and the wet processing module 1B to the other one thereof. As described hereinafter, the dry processing module 1A performs dry processing on the substrate W in a vacuum state, and the wet processing module 1B performs wet processing on the substrate W in an atmospheric pressure state. The main transporter 80 transports the substrate W processed by both the dry processing module 1A and the wet processing module 1B to the transfer part 123, for example.

In the example in FIG. 1, the main transporter 80 is provided in the main transportation space TS. The main transportation space TS extends along a predetermined movement direction Dx. The movement direction Dx is a direction along a horizontal direction, for example. In the example in FIG. 1, the movement direction Dx is a direction perpendicular to an arrangement direction of the load port 111. The horizontal direction perpendicular to the movement direction Dx is also referred to as a width direction Dy (the same as the arrangement direction herein) hereinafter. A size of the movement direction Dx of the main transportation space TS is larger than that of the width direction Dy of the main transportation space TS. That is to say, the main transportation space TS has an elongated shape elongated in the movement direction Dx in a plan view. The plan view herein indicates seeing a target object along the vertical direction.

In the example in FIG. 1, a plurality of processing modules 1 are provided to one side (a first side) of the main transportation space TS in the width direction Dy. The plurality of these processing modules 1 are also referred to as a first module group G1 hereinafter. In the example in FIG. 1, the plurality of (two in FIG. 1) processing modules 1 are arranged in the movement direction Dx (that is to say, a longitudinal direction of the main transportation space TS) in the first module group G1. The first module group G1 also has an elongated shape elongated in the movement direction Dx in the manner similar to the main transportation space TS.

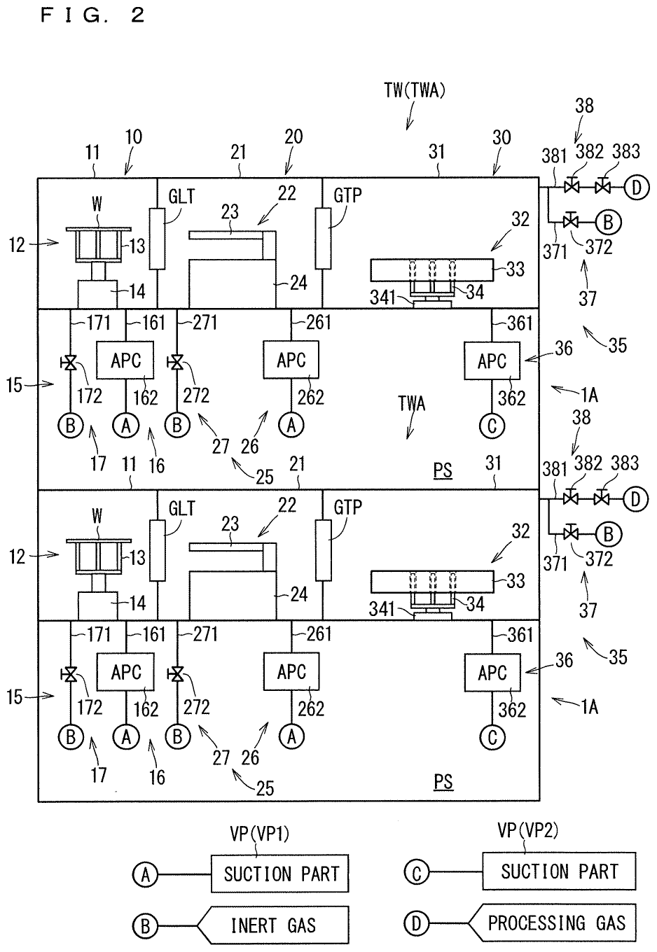

In the example in FIG. 1, a plurality of processing modules 1 are also provided to the other side (a second side) of the main transportation space TS in the width direction Dy. The plurality of these processing modules 1 are also referred to as a second module group G2 hereinafter. In the example in FIG. 1, since the second module group G2 is provided to the other side of the main transportation space TS, the main transportation space TS is located between the first module group G1 and the second module group G2. In the example in FIG. 1, the plurality of (two in FIG. 2) processing modules 1 are arranged in the movement direction Dx (that is to say, the longitudinal direction of the main transportation space TS) in the second module group G2. The second module group G2 also has an elongated shape elongated in the movement direction Dx in the manner similar to the main transportation space TS.

The plurality of (herein, four) processing modules 1 are provided in a plan view. The plurality of processing modules 1 may be stacked in the vertical direction in a position where each processing module 1 is provided. When a part including the plurality of processing modules 1 stacked in the vertical direction is referred to as a tower TW, in the example in FIG. 1, the first module group G1 is made up of a plurality of (two in FIG. 1) towers TW arranged along the movement direction Dx, and the second module group G2 is made up of a plurality of (two in FIG. 1) towers TW arranged along the movement direction Dx.

In the example in FIG. 1, the main transportation space TS and the transfer part 123 are arranged in the movement direction Dx. The transfer part 123 is provided closer to the indexer block 110 in relation to the main transportation space TS. In the example in FIG. 1, the transfer part 123 is provided to a position adjacent to a center part of the indexer block 110. The main transporter 80 can be moved along the movement direction Dx in the main transportation space TS. The main transporter 80 can be moved to a transfer position corresponding to each of the transfer part 123 and the plurality of processing modules 1 in the main transportation space TS. The main transporter 80 transports the substrate W into and out of the transfer part 123 or the processing module 1 in each transfer position.

Each processing module 1 includes a module transportation gate GMT. The module transportation gate GMT is provided to a boundary between the processing module 1 and the main transportation space TS. The module transportation gate GMT is an openable and closable transportation port, and its opening and closing are controlled by the controller 90. The module transportation gate GMT may also be a gate valve or a shutter. This point also applies to the other gate described hereinafter. The main transporter 80 stops at a transfer position facing the module transportation gate GMT. Then, the main transporter 80 transports the substrate W into and out of the processing module 1 through the module transportation gate GMT in an open state. In a state where the module transportation gate GMT is closed, an inner space of the processing module 1 is blocked from the main transportation space TS.

The main transporter 80 transports the unprocessed substrate W from the transfer part 123 to the dry processing module 1A. The dry processing module 1A performs dry processing on the substrate W. The dry processing is processing of etching an etching target object on a main surface of the substrate W, for example. There is a case where an impurity remains on the main surface of the substrate W by this dry processing. The main transporter 80 transports the substrate W on which dry processing has been performed from the dry processing module 1A to the wet processing module 1B. Then, the wet processing module 1B performs wet processing on the substrate W on which the dry processing has been performed. The wet processing is washing processing of removing the impurity on the main surface of the substrate W, for example. At least a part of the impurity of the substrate W can be removed by this wet processing. The main transporter 80 transports the substrate W on which the wet processing has been performed from the wet processing module 1B to the transfer part 123.

### Dry Processing Module

Next, a configuration of the dry processing module 1A is briefly described, and then described in detail. The dry processing module 1A includes the load lock unit 10, the local transportation unit 20, and a dry processing unit 30. The load lock unit 10 includes the load lock chamber 11, the local transportation unit 20 includes the local transportation chamber 21, and the dry processing unit 30 includes the dry processing chamber 31. The load lock chamber 11 is connected to the local transportation chamber 21 via the load transportation gate GLT, and the local transportation chamber 21 is connected to the dry processing chamber 31 via the transportation processing gate GTP. The load lock unit 10 is an interface of the dry processing module 1A. The load lock chamber 11 includes the dry transportation gate GDT as the module transportation gate GMT. The dry transportation gate GDT is provided to a part of the load lock chamber 11 facing the main transportation space TS.

The load lock unit 10 switches an atmospheric pressure state and a vacuum state. That is to say, the load lock unit 10 changes the state of the load lock chamber 11 between an atmospheric pressure state and a vacuum state. The main transporter 80 transports the load lock unit 10 and the substrate W in an atmospheric pressure state. That is to say, the main transporter 80 transports the substrate W into and out of the load lock chamber 11 in the atmospheric pressure state through the dry transportation gate GDT.

The local transportation unit 20 includes the local transporter 22. The local transporter 22 is provided in the local transportation chamber 21. The local transporter 22 is controlled by the controller 90, and transports the substrate W between the load lock unit 10 and the dry processing unit 30 in a vacuum state.

The dry processing unit 30 performs dry processing on the substrate W in a vacuum state.

In the example in FIG. 1, the local transportation chamber 21 is adjacent to the load lock chamber 11 in the movement direction Dx. In the example in FIG. 1, the dry processing chamber 31 is adjacent to the local transportation chamber 21 in the movement direction Dx. That is to say, in the example in FIG. 1, the load lock chamber 11, the local transportation chamber 21, and the dry processing chamber 31 are arranged in this order in the movement direction Dx (that is to say, the longitudinal direction of the main transportation space TS). In such an arrangement, the local transportation chamber 21 is provided between the load lock chamber 11 and the dry processing chamber 31. In the example in FIG. 1, the load lock unit 10, the local transportation unit 20, and the dry processing unit 30 are provided one by one in each dry processing module 1A. In other words, each of the load lock unit 10 and the local transportation unit 20 is a unit dedicated to the single dry processing unit 30.

In such a dry processing module 1A, the main transporter 80 transports the unprocessed substrate W into the load lock chamber 11 in an atmospheric pressure state. Next, the load lock unit 10 reduces pressure in the load lock chamber 11 to within a vacuum range. Then, the local transporter 22 takes out the substrate W from the load lock chamber 11 in a vacuum state, and transports the substrate W into the dry processing chamber 31. The dry processing unit 30 performs dry processing on the substrate W in the dry processing chamber 31. The local transporter 22 takes out the substrate W on which dry processing has been performed from the dry processing chamber 31, and transports the substrate W into the load lock chamber 11. Then, the main transporter 80 takes out the substrate W from the load lock chamber 11 while the load lock unit 10 increases pressure in the load lock chamber 11 to within an atmospheric pressure range.

FIG. 2 is a vertical cross-sectional view schematically illustrating an example of a specific configuration of the dry processing module 1A. In the example in FIG. 2, two dry processing modules 1A are stacked in the vertical direction, and this point is described hereinafter.

### Load Lock Unit

As illustrated in FIG. 2, the load lock unit 10 includes a substrate disposed part 12 and the first pressure adjuster 15 in addition to the load lock chamber 11.

The substrate disposed part 12 is provided in the load lock chamber 11, and supports or holds the substrate W in a horizontal posture. The horizontal posture herein indicates a posture in which a thickness direction of the substrate W extends along the vertical direction. In the example in FIG. 2, the substrate disposed part 12 includes a plurality of (for example, three or more) support pins 13. Each support pin 13 has a rod-like shape extending along the vertical direction, and a distal end thereof has contact with a lower surface of the substrate W. In this state, the plurality of support pins 13 support the substrate W in the horizontal posture. The substrate disposed part 12 may be a plate-like stage supporting the substrate W, and may also be a suction stage sucking and holding the substrate W. In the example in FIG. 2, the substrate disposed part 12 supports or holds the single substrate W.

The first pressure adjuster 15 adjusts pressure in the load lock chamber 11. For example, the first pressure adjuster 15 adjusts pressure in the load lock chamber 11 to a value within an atmospheric pressure range. Accordingly, the load lock chamber 11 enters the atmospheric pressure state. The atmospheric pressure range is a range including normal atmospheric pressure, and may be equal to or larger than 80% and equal to or smaller than 120% of the normal atmospheric pressure as an example. The first pressure adjuster 15 adjusts pressure in the load lock chamber 11 to a value within a vacuum range lower than the atmospheric pressure range. Accordingly, the load lock chamber 11 enters the vacuum state. The vacuum range may be one-tenth of normal atmospheric pressure or less, or may also be one-hundredth of normal atmospheric pressure or less.

In the example in FIG. 2, the first pressure adjuster 15 includes a first gas suction part 16 and a first gas supply part 17. The first gas supply part 17 supplies gas into the load lock chamber 11. The gas is inert gas, for example. The inert gas includes at least one of noble gas and nitrogen gas, for example. The noble gas includes at least one of argon gas and neon gas. The first gas suction part 16 sucks gas from inside the load lock chamber 11.

In the example in FIG. 2, the first gas supply part 17 includes a first supply pipe 171 and a first supply valve 172. A downstream end of the first supply pipe 171 is connected to a bottom part, for example, of the load lock chamber 11. An upstream end of the first supply pipe 171 is connected to an inert gas supply source. The inert gas supply source includes a retention part (not shown) retaining the inert gas. The first supply valve 172 is provided to the first supply pipe 171. The first supply valve 172 is controlled by the controller 90, and switches opening and closing of the first supply pipe 171.

In the example in FIG. 2, the first gas suction part 16 includes a first suction pipe (corresponding to an example of a first gas pipe) 161, a first pressure adjustment valve 162, and a suction part VP. An upstream end of the first suction pipe 161 is connected to a bottom part, for example, of the load lock chamber 11. A downstream end of the first suction pipe 161 is connected to the suction part VP. The suction part VP is a pump, for example, and is controlled by the controller 90. The suction part VP sucks gas inside the load lock chamber 11 through the first suction pipe 161. The first pressure adjustment valve 162 is provided to the first suction pipe 161. The controller 90 controls the first pressure adjustment valve 162. The first pressure adjustment valve 162 adjusts an opening degree of itself to adjust pressure in the load lock chamber 11. The first pressure adjustment valve 162 is an automatic pressure controller, for example. The first pressure adjustment valve 162 may include a built-in pressure sensor, or a pressure sensor may be provided to the load lock chamber 11. The first pressure adjustment valve 162 adjusts the opening degree thereof in accordance with a detection value of the pressure sensor, thus can adjust pressure in the load lock chamber 11 with higher accuracy. The same applies to the other pressure adjustment valve described hereinafter.

Each of the dry transportation gate GDT and the load transportation gate GLT of the load lock chamber 11 is an openable and closable transportation port, and is controlled by the controller 90. The dry transportation gate GDT is opened and closed in a state where pressure in the load lock chamber 11 is within an atmospheric pressure range. The main transporter 80 transports the substrate W into and out of the load lock chamber 11 through the dry transportation gate GDT while the dry transportation gate GDT is opened. The load transportation gate GLT is opened and closed in a state where pressure in the load lock chamber 11 and pressure in the local transportation chamber 21 are within a vacuum range. The local transporter 22 transports the substrate W into and out of the load lock chamber 11 through the load transportation gate GLT while the load transportation gate GLT is opened.

### Local Transportation Unit

The local transportation unit 20 includes a second pressure adjuster 25 in addition to the local transportation chamber 21 and the local transporter 22.

The local transporter 22 is a transfer robot, and is controller by the controller 90. As illustrated in FIG. 2, the local transporter 22 includes a hand 23 and a hand movement driver 24. The hand 23 has a plate-like shape, for example. The hand 23 holds or supports the substrate W in a horizontal posture. For example, the substrate W is disposed on the hand 23. The hand movement driver 24 is controlled by the controller 90, and moves the hand 23. For example, the hand movement driver 24 includes a drive source such as a motor and a power transmission part transmitting drive force of the drive source to the hand 23. The power transmission part includes at least one of an arm mechanism, a ball spring mechanism, a rotation mechanism, and a cam mechanism, for example.

The second pressure adjuster 25 adjusts pressure in the local transportation chamber 21. Specifically, the second pressure adjuster 25 adjusts pressure in the local transportation chamber 21 to a value within a vacuum range. Accordingly, the local transportation chamber 21 enters the vacuum state. The second pressure adjuster 25 includes a second gas suction part 26 and a second gas supply part 27. The second gas supply part 27 supplies gas (for example, inert gas) into the local transportation chamber 21. The second gas suction part 26 sucks gas from inside the local transportation chamber 21. In the example in FIG. 2, the second gas supply part 27 includes a second supply pipe 271 and a second supply valve 272, and the second gas suction part 26 includes a second suction pipe (corresponding to an example of the second gas pipe) 261, a second pressure adjustment valve 262, and the suction part VP. Since these configurations are similar to those of the first pressure adjuster 15, the detailed specification is omitted.

The transportation processing gate GTP is an openable and closable transfer port, and is controlled by the controller 90. The transportation processing gate GTP is opened and closed in a state where pressure in the local transportation chamber 21 and pressure in the dry processing chamber 31 are within a vacuum range. The local transporter 22 transports the substrate W into and out of the dry processing chamber 31 through the transportation processing gate GTP while the transportation processing gate GTP is opened.

### Dry Processing Unit

The dry processing unit 30 includes a substrate disposed part 32, a third pressure adjuster 35, and a processing gas supply part 38 in addition to the dry processing chamber 31.

The substrate disposed part 32 is provided in the dry processing chamber 31, and supports or holds the substrate W in the horizontal posture. In the example in FIG. 2, the substrate disposed part 32 includes the stage 33 and the plurality of elevating pins 34. The stage 33 has a plate-like shape, and is provided in a posture so that a thickness direction thereof extends along the vertical direction. The substrate W is disposed on the stage 33 in the horizontal posture.

The elevating pin 34 has a rod-like shape extending along the vertical direction, and at least a part of the elevating pin 34 is disposed to pass through the stage 33. The elevating pin 34 is moved up and down between the first height position and the second height position by the pin elevating driver 341. The first height position is a position where a distal end of the elevating pin 34 is located above an upper surface of the stage 33, and the second height position is a position where a distal end of the elevating pin 34 is located below the upper surface of the stage 33. The controller 90 controls the pin elevating driver 341. For example, the pin elevating driver 341 includes a drive source such as a motor or a pump and a power transmission part transmitting drive force of the drive source to the elevating pin 34. The power transmission part includes a ball spring mechanism or an air cylinder, for example. The substrate W can be transferred between the stage 33 and the local transporter 22 by moving up and down the elevating pin 34.

The third pressure adjuster 35 adjusts pressure in the dry processing chamber 31. Specifically, the third pressure adjuster 35 adjusts pressure in the dry processing chamber 31 to a value within a vacuum range. Accordingly, the dry processing chamber 31 enters the vacuum state. The third pressure adjuster 35 includes a third gas suction part 36 and a third gas supply part 37. The third gas supply part 37 supplies gas (for example, inert gas) into the dry processing chamber 31. The third gas suction part 36 sucks gas from inside the dry processing chamber 31. In the example in FIG. 2, the third gas supply part 37 includes a third supply pipe 371 and a third supply valve 373, and the third gas suction part 36 includes a third suction pipe (corresponding to an example of the third gas pipe) 361, a third pressure adjustment valve 362, and the suction part VP. Since these configurations are similar to those of the first pressure adjuster 15, the detailed description is omitted. In the example in FIG. 2, a downstream end of the third supply pipe 371 is connected to a side part of the dry processing chamber 31.

The processing gas supply part 38 supplies processing gas into the dry processing chamber 31. The processing gas acts on a main surface (the upper surface herein) of the substrate W disposed on a substrate disposed part 32 (specifically, the stage 33). Accordingly, dry processing corresponding to a type of the processing gas is performed on the main surface of the substrate W. As an example, the processing gas is etching gas. The etching gas removes an etching target object of the substrate W. As a specific example, the processing gas may include hydrogen fluoride gas, and may further include moisture vapor. When the hydrogen fluoride gas (and moisture vapor) acts on an oxide film (a silicon oxide film, for example) of the substrate W, the oxide film can be etched. A component of the processing gas (fluorine, for example) may remain on the main surface of the substrate W by this dry processing, or a residual product or a residual of the etching target object may remain in some cases.

In the example in FIG. 2, the processing gas supply part 38 includes a supply pipe 381, a supply valve 382, and a flow amount adjustment valve 383. A downstream end of the supply pipe 381 is connected to a side part, for example, of the dry processing chamber 31. In the example in FIG. 2, the supply pipe 381 and the third supply pipe 371 join up with a common pipe, and a downstream end of the common pipe is connected to a side part of the dry processing chamber 31. An upstream end of the supply pipe 381 is connected to a processing gas supply source. The processing gas supply source includes a retention part (not shown) retaining the processing gas. The supply valve 382 and the flow amount adjustment valve 383 are provided to the supply pipe 381. The supply valve 382 is controlled by the controller 90, and switches opening and closing of the supply pipe 381. The flow amount adjustment valve 383 is controlled by the controller 90, and adjusts a flow amount of the processing gas flowing in the supply pipe 381. When the processing gas includes plural types of gas, the supply pipe 381, the supply valve 382, and the flow amount adjustment valve 383 corresponding to each type may be provided.

The dry processing unit 30 may include a plasma reactor converting the processing gas into plasma. The plasma reactor may be a capacitive coupled plasma reactor or an inductive coupled plasma reactor, for example. It is also applicable that the dry processing unit 30 makes various active species (ion or radical, for example) included in plasma act on the main surface of the substrate W, thereby performing plasma processing on the substrate W.

### Wet Processing Module

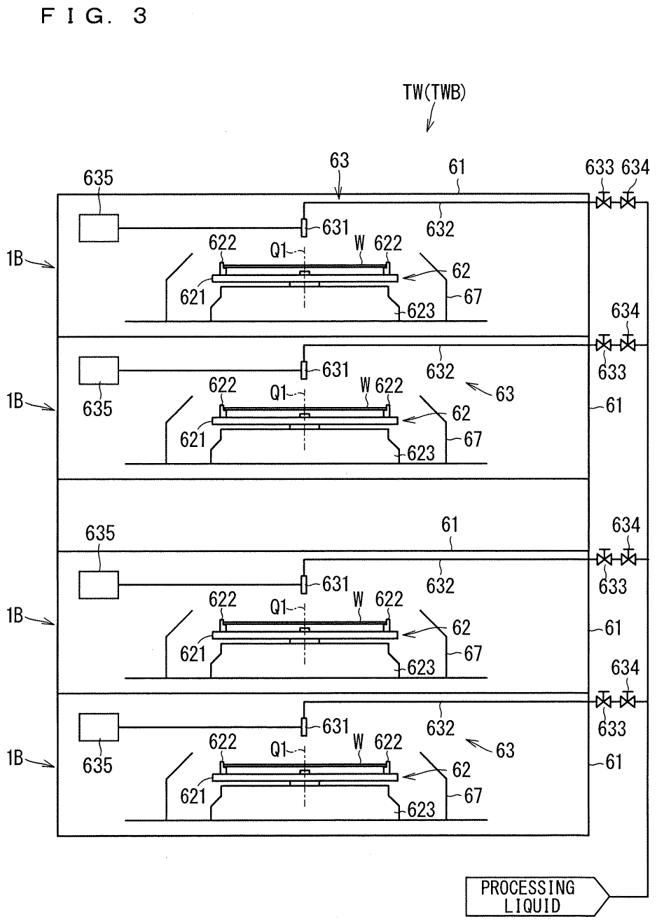

FIG. 3 is a vertical cross-sectional view schematically illustrating an example of a configuration of the wet processing module 1B. In the example in FIG. 3, four wet processing modules 1B are stacked in the vertical direction, and this point is described hereinafter.

As illustrated in FIG. 3, the wet processing module 1B includes a wet processing chamber 61, a substrate holder 62, and a discharger 63.

The wet processing chamber 61 forms a wet processing space for performing wet processing on the substrate W. Pressure in the wet processing chamber 61 is within an atmospheric pressure range. A pressure adjuster may be provided to the wet processing module 1B in the manner similar to the dry processing module 1A. The pressure adjuster can adjust pressure in the wet processing module 1B within an atmospheric pressure range.

As illustrated in FIG. 1, a wet transportation gate GWT as the module transportation gate GMT is provided to a part of the wet processing chamber 61 facing the main transportation space TS. The wet transportation gate GWT is an openable and closable transportation port, and is controlled by the controller 90. The main transporter 80 transports the substrate W into and out of the wet processing chamber 61 through the wet transportation gate GWT while the wet transportation gate GWT is opened.

The substrate holder 62 is provided inside the wet processing chamber 61. The substrate holder 62 rotates the substrate W around a rotation axis line Q1 while holding the substrate W in the horizonal posture. The rotation axis line Q1 is an axis extending along the vertical direction through a center of the substrate W. The substrate holder 62 is also referred to as a spin chuck.

In the example in FIG. 3, the substrate holder 62 includes a spin base 621, a chuck pin 622, and a rotation driver 623. The spin base 621 has a plate-like shape (for example, a disk-like shape), and is provided in a posture so that a thickness direction thereof extends along the vertical direction. The plurality of chuck pins 622 are provided to an upper surface of the spin base 621. The plurality of chuck pins 622 are provided at regular intervals along a circumferential direction of the rotation axis line Q1. The plurality of chuck pins 622 are provided to be able to be displaced between a holding position and a release position described next. The holding position is a position where the chuck pin 622 has direct contact with a peripheral edge of the substate W. When the plurality of chuck pins 622 stop at respective holding positions, the plurality of chuck pins 622 hold the substate W. FIG. 3 illustrates the chuck pins 622 stopping at the holding positions. The release position is a position where each chuck pin 622 is away from the substate W. When the plurality of chuck pins 622 stop at respective release positions, holding of the substate W by the plurality of chuck pins 622 is released. The substrate holder 62 also includes a pin driver (not shown) displacing the chuck pin 622. The pin driver includes a drive source such as a motor or an air cylinder, for example, and is controlled by the controller 90.

The rotation driver 623 is controlled by the controller 90, and rotates the spin base 621 around the rotation axis line Q1. The rotation driver 623 includes a shaft and a motor, for example. An upper end of the shaft is connected to a lower surface of the spin base 621, and the shaft extends along the rotation axis line Q1 from the lower surface of the spin base 621. The motor is controlled by the controller 90, and rotates the shaft around the rotation axis line Q1. Accordingly, the spin base 621, the chuck pin 622, and the substate W are integrally rotated around the rotation axis line Q1.

The substrate holder 62 needs not necessarily include the chuck pin 622. For example, the substrate holder 62 may hold the substate W by a chuck system such as vacuum chuck, electrostatic chuck, and Bernoulli chuck.

The discharger 63 sequentially discharges various processing liquids toward a main surface of the substrate W held by the substrate holder 62. The processing liquid includes a chemical solution and a rinse solution, for example. The chemical solution is a fluid chemically reacting with the main surface of the substrate W, and includes a solution removing an impurity on the main surface of the substrate W, for example. As a specific example, the chemical solution includes at least one of a mixed solution (SC1) of hydrofluoric acid, sulfuric acid, nitric acid, or ammonium hydroxide and hydrogen peroxide, a mixed solution (SC2) of hydrochloric acid and hydrogen peroxide, and a mixed solution (SPM) of sulfuric acid and hydrogen peroxide. The rinse solution is a fluid physically washing away at least one of a fluid and a solid (for example, particles) on the main surface of the substrate W, and includes at least one of pure water (deionization water), carbon dioxide water, and an organic solvent, for example. The organic solvent includes isopropyl alcohol, for example.

In the example in FIG. 3, the discharger 63 includes a nozzle 631, a supply pipe 632, a supply valve 633, and a flow amount adjustment valve 634. The nozzle 631 is provided in the wet processing chamber 61, and discharges the processing liquid toward the main surface of the substrate W held by the substrate holder 62. In the example in FIG. 3, the nozzle 631 is provided above the substrate W held by the substrate holder 62.

A downstream end of the supply pipe 632 is connected to the nozzle 631, and an upstream end of the supply pipe 632 is connected to a processing liquid supply source. The processing liquid supply source includes a tank (not shown) retaining the processing liquid. The supply valve 632 and the flow amount adjustment valve 634 are provided to the supply pipe 632. The supply valve 633 is controlled by the controller 90, and switches opening and closing of the supply pipe 632. The flow amount adjustment valve 634 is controlled by the controller 90, and adjusts a flow amount of the processing liquid flowing in the supply pipe 632. When the processing liquid includes plural types of fluid, the nozzle 631, the supply pipe 632, the supply valve 633, and the flow amount adjustment valve 634 corresponding to each type may be provided. The nozzle 631 may be used in common by two or more types of fluid.

In the example in FIG. 3, a nozzle movement driver 635 is connected to the nozzle 631. The nozzle movement driver 635 is controlled by the controller 90, and moves the nozzle 631 between a processing position and a standby position described next. The processing position is a position where the nozzle 631 discharges the processing liquid, and is a position facing a center part of the substrate W in the vertical direction, for example. FIG. 3 illustrates an example of the nozzle 631 stopped at the processing position. The standby position is a position where the nozzle 631 does not discharge the processing liquid toward the substate W, and is a position on an outer side than the substate W in a radial direction, for example. The nozzle movement driver 635 may have an arm slewing mechanism, for example. For example, the arm slewing mechanism includes an arm not shown, a support column and a drive source. The support column is provided on an outer side than a guard 67 described hereinafter in a radial direction, and extends along the vertical direction. The arm extends along a horizontal direction, a tip end thereof is connected to the nozzle 631, and a base end thereof is connected to the support column. The drive source is controlled by the controller 90, and rotates the support column in a forward-reverse direction within a predetermined angular range. The drive source includes a motor, for example. When the support column is rotated in the forward-reverse direction within the predetermined angular range, the nozzle 631 reciprocates along a circumferential direction around the support column as a rotation axis line. The support column is disposed so that the processing position and the standby position are located on a movement trajectory of the nozzle 631. The nozzle movement driver 635 needs not necessarily have the arm slewing mechanism, but may include a direct acting mechanism such as a linear motor, for example.

When the discharger 63 sequentially supplies the processing liquid while the substrate holder 62 rotates the substrate W, processing corresponding to the type of the processing liquid can be sequentially performed on the substrate W. As an example, the discharger 63 firstly discharges a chemical solution to the main surface of the substrate W, thereby performing chemical solution processing on the main surface of the substrate W. Accordingly, an impurity remaining on the main surface of the substrate W in dry processing by the dry processing module 1A can be removed, for example. Next, the discharger 63 discharges the rinse solution to the main surface of the substrate W, thereby washing away the chemical solution on the main surface of the substrate W to outside in the radial direction. Accordingly, the processing liquid which is the chemical solution on the main surface of the substrate W is replaced with the rinse solution. Next, the substrate holder 62 increases a rotation speed of the substrate W to dry the substrate W while the discharger 63 stops discharging the processing liquid.

In the example in FIG. 3, the guard 67 is provided in the wet processing chamber 61. The guard 67 has a cylindrical shape surrounding the substrate holder 62, and receives the processing liquid flying from the peripheral edge of the substrate W. The processing liquid received by the guard 67 flows down the guard 67, and is discharged outside through a discharge pipe not shown.

### Main Transporter

With reference to FIG. 1, the main transporter 80 is provided in the main transportation space TS. A transportation movement driver 85 is provided to the main transporter 80. The transportation movement driver 85 is controlled by the controller 90, and moves the main transporter 80 in the movement direction Dx. For example, the transportation movement driver 85 includes a drive source such as a motor and a power transmission part transmitting drive force of the drive source to the main transporter 80. The power transmission part includes a ball spring mechanism, for example.

The main transporter 80 includes at least one hand 81 and a hand movement driver 82 driving the hand 81. The main transporter 80 may include the plurality of (for example, four) hands 81. The hand movement driver 82 may include an advancing-retracting driver, a rotation driver, and an elevating driver not shown, for example. The advancing-retracting driver moves the plurality of hands 81 independently along each predetermined advancing-retracting direction. For example, the advancing-retracting driver includes an arm driver provided to correspond to each hand 81. The arm driver includes a plurality of arms and a motor adjusting a connection angle of the plurality of arms. The hand 81 is connected to one end of a connector including the plurality of arms, and the other end thereof is connected to the rotation driver. When the connection angle of the arm is adjusted, the hand 81 is moved along the advancing-retracting direction. The rotation driver includes a motor, and integrally rotates the hand 81 and the advancing-retracting driver around a rotational axis line along the vertical direction. A direction of the hand 81 (that is to say, the advancing-retracting direction) can be adjusted by this rotation. The elevating driver integrally moves up and down the hand 81, the advancing-retracting driver, and the rotation driver. The hand 81 can be moved to a height position appropriate for each of the transfer part 123 and the processing module 1 by moving up and down them. For example, the elevating driver includes a drive source such as a motor and a power transmission part transmitting drive force of the drive source to the hand 81. The power transmission part includes a ball spring mechanism or a cam mechanism, for example.

### Controller

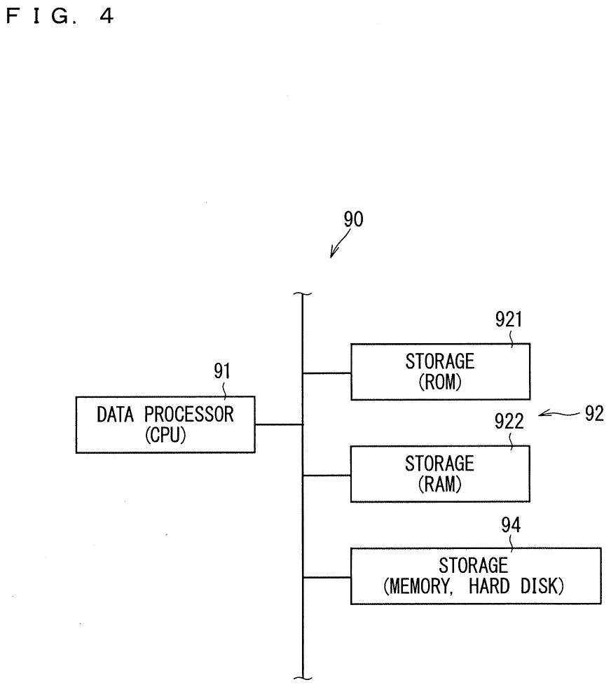

FIG. 4 is a diagram schematically illustrating an example of an inner configuration of the controller 90. The controller 90 collectively controls the substrate processing apparatus 100. The controller 90 is an electrical circuit, and includes a data processor 91 and a storage 92, for example. The data processor 91 and the storage 92 may be mutually connected to each other via a bus 93. The data processor 91 may be an arithmetic processing unit such as a central processor unit (CPU), for example. The storage 92 may include a non-transitory storage (for example, a read only memory (ROM)) 921 and a transitory storage (for example, a random access memory (RAM)) 922. The non-transitory storage 921 may store a program regulating processing executed by the controller 90, for example. When the data processor 91 executes this program, the controller 90 can execute processing regulated by the program. Needless to say, hardware such as a dedicated logic circuit may execute part of or whole processing executed by the controller 90. In the example in FIG. 4, the controller 90 is also connected to a non-transitory storage 94 (a memory such as a flash memory or a hard disk).

As described above, the substrate processing apparatus 100 according to the first embodiment includes the plurality of dry processing modules 1A, the wet processing module 1B, and the main transporter 80, and the main transporter 80 transports the substrate W between the dry processing module 1A and the wet processing module 1B. Each dry processing module 1A includes the load lock unit 10, the local transportation unit 20, and the dry processing unit 30. Thus, the main transporter 80 can transport the substrate W to the other dry processing module 1A during operation of the dry processing module 1A (for example, during pressure adjustment, during transportation of the substrate W by the local transporter 22, or during dry processing by the dry processing unit 30). Thus, the main transporter 80 can transport the substrate W into and out of the dry processing module 1A by higher throughput.

In the example described above, each of the load lock unit 10 and the local transportation unit 20 is provided one by one for the dry processing unit 30. Thus, the local transportation unit 20 can transport the substrate W to the dry processing unit 30 more rapidly. That is to say, when the local transportation unit 20 is provided to correspond to the plurality of dry processing units 30, the substrate W cannot be transported into and out of the other dry processing unit 30 in a period in which the local transportation unit 20 transports the substrate W into and out of a certain dry processing unit 30, and a standby time occurs. In the meanwhile, when the local transportation unit 20 is provided one by one for the dry processing unit 30, this standby time does not occur. Thus, the substrate W can be transported into and out of the dry processing unit 30 with higher throughput.

In the example described above, a plurality of wet processing modules 1B are provided. Thus, the main transporter 80 can transport the substrate W to the other wet processing module 1B without waiting for finish of the wet processing in a certain wet processing module 1B after the main transporter 80 transports the substrate W to the certain wet processing module 1B. Thus, the main transporter 80 can transport the substrate W into and out of the wet processing module 1B by higher throughput.

The main transporter 80 can transport the substrate W to each processing module 1 stacked in the vertical direction. That is to say, an elevating range of the hand 81 of the main transporter 80 is set within a range such that the hand 81 can be stopped at a height position corresponding to each of the processing module 1 on an uppermost stage and the processing module 1 on a lowermost stage. Thus, even when the dry processing module 1A and the wet processing module 1B are provided in height positions different from each other, the main transporter 80 can transport the substrate W between the dry processing module 1A and the wet processing module 1B. Accordingly, the number of processing modules 1 in each tower TW can be different between the plurality of towers TW. That is to say, a degree of freedom of placing the dry processing module 1A and the wet processing module 1B can be improved.

In the example described above, in each the dry processing module 1A, the load lock unit 10 (specifically, the load lock chamber 11), the local transportation unit 20 (specifically, the local transportation chamber 21), and the dry processing unit 30 (specifically, the dry processing chamber 31) are arranged along the movement direction Dx. Thus, a worker can come and go to a space on an opposite side of each load lock unit 10 from the main transportation space TS. With reference to FIG. 1, for example, a worker can come and go to a space on an opposite side of the first module group G1 from the main transportation space TS. Accordingly, the worker can easily perform maintenance on each load lock unit 10 of the first module group G1. The same applies to the local transportation unit 20 and the dry processing unit 30 of the first module group G1. In the example in FIG. 1, a worker can come and go to a space on an opposite side of the second module group G2 from the main transportation space TS. Thus, maintenance on the load lock unit 10, the local transportation unit 20, and the dry processing unit 30 of the second module group G2 is also easily performed.

### Positions of Dry Processing Module and Wet Processing Module

The load lock unit 10, the local transportation unit 20, and the dry processing unit 30 are arranged in this order in the movement direction Dx in each dry processing module 1A. Thus, the dry transportation gate GDT provided to the load lock unit 10 is located on an end side of the dry processing module 1A in the movement direction Dx.

In the example in FIG. 1, the first module group G1 includes one or more (one in FIG. 1) dry processing modules 1A and one or more (one in FIG. 1) wet processing modules 1B. The dry processing module 1A and the wet processing module 1B are arranged along the movement direction Dx in the first module group G1.

In the example in FIG. 1, the dry processing unit 30, the local transportation unit 20, and the load lock unit 10 are provided in this order as getting away from the indexer block 110 (or the transfer part 123) in this first module group G1. In the description herein, a first end and a second end of the main transportation space TS in a longitudinal direction are introduced. The first end of the main transportation space TS is an end on a side of the transfer part 123, and the second end is an end on a side opposite to the first end. The dry processing unit 30, the local transportation unit 20, and the load lock unit 10 are arranged in this order in a direction from the first end toward the second end of the main transportation space TS in the longitudinal direction. That is to say, the load lock unit 10 is provided in a position farther away than the indexer block 110 in the dry processing module 1A. Thus, even when the whole first module group G1 is provided in a position closer to the indexer block 110 in the movement direction Dx, the dry transportation gate GDT can face the main transportation space TS. In the example in FIG. 1, the first module group G1 is provided so that a part of the first module group G1 on the side of the indexer block 110 faces the transfer part 123 in the width direction Dy. That is to say, at least a part of the dry processing unit 30 closest to the indexer block 110 in the first module group G1 faces the transfer part 123 in the width direction Dy. Further in other words, an end G1a of the first module group G1 on the side of the indexer block 110 is located closer to the side of the indexer block 110 in relation to an end 123b of the transfer part 123 on a side opposite to the indexer block 110.

The end 123b of the transfer part 123 is located closer to the side of the indexer block 110 than the module transportation gate GMT closest to the side of the indexer block 110 in the first module group G1. Thus, the whole module transportation gate GMT of the first module group G1 can face the main transportation space TS. In the specific example in FIG. 1, the end 123b of the transfer part 123 is located closer to the side of the indexer block 110 than the end G1b of the dry processing unit 30 closest to the indexer block 110 in the first module group G1. The end G1b is an end on a side opposite to the end G1a.

When the first module group G1 is provided closer to the indexer block 110 in the movement direction Dx, a transportation distance between the transfer part 123 and the module transportation gate GMT can be reduced. Accordingly, the main transporter 80 can transport the substrate W more rapidly between the transfer part 123 and each processing module 1 of first module group G1.

In the example in FIG. 1, the wet processing module 1B is provided in a last stage position farthest away from the indexer block 110 (or the transfer part 123) in the first module group G1. That is to say, the processing module 1 located farthest away from the indexer block 110 in the first module group G1 is the wet processing module 1B. Three chambers are arranged in the movement direction Dx in the dry processing module 1A. In the meanwhile, the wet processing module 1B includes the single wet processing chamber 61 into and out of which the substrate W is transported. Thus, the wet transportation gate GWT can be located closer to a center side of the processing module 1 in the movement direction Dx compared with the dry transportation gate GDT.

Herein, a whole configuration of the load lock chamber 11, the local transportation chamber 21, and the dry processing chamber 31 is referred to as a dry chamber. A size of the dry chamber in the movement direction Dx and a size of the wet processing chamber 61 in the movement direction Dx are substantially the same as each other.

FIG. 1 illustrates an example of the dry transportation gate GDT by a dash-double-dot line in a case where the dry processing module 1A is disposed in a last stage position of the first module group G1. As recognizable from FIG. 1, when the wet processing module 1B is provided in the last stage position, a position of the module transportation gate GMT in a last stage position can be brought closer to the indexer block 110. Accordingly, a transportation distance between the module transportation gate GMT of the wet processing module 1B in a last stage and the transfer part 123 or the module transportation gate GMT of the dry processing module 1A can be reduced. Accordingly, the main transporter 80 can transport the substrate W more rapidly between the wet processing module 1B in the last stage and the transfer part 123 or the dry processing module 1A.

In the meanwhile, in the example in FIG. 1, the second module group G2 includes the plurality of processing modules 1, and at least one (two in FIG. 1) processing module 1 is the dry processing module 1A. The load lock unit 10, the local transportation unit 20, and the dry processing unit 30 are provided in this order as getting away from the indexer block 110 (or the transfer part 123) in the second module group G2. In other words, the load lock unit 10, the local transportation unit 20, and the dry processing unit 30 are arranged in this order in a direction from the first end toward the second end of the main transportation space TS in the longitudinal direction. That is to say, an arrangement order of the units of the dry processing module 1A in the second module group G2 is opposite to that of the units of the dry processing module 1A in the first module group G1.

The dry processing module 1A of the second module group G2 may have a configuration obtained by rotating the dry processing module 1A of the first module group G1 at 180 degrees around a rotation axis line along the vertical direction. According to this configuration, the configuration of the dry processing module 1A of the first module group G1 and the configuration of the dry processing module 1A of the second module group G2 can be the same as each other. Accordingly, the dry processing module 1A of the first module group G1 and the second module group G2 can be manufactured with lower cost.

When such a second module group G2 is provided closer to the indexer block 110, there is a possibility that the dry transportation gate GDT located closest to the indexer block 110 faces the transfer part 123 in the width direction DY. In this case, the main transporter 80 interfaces with the transfer part 123, and cannot have access to the dry transportation gate GDT. Thus, in the example in FIG. 1, the second module group G2 is provided so that the position of the second module group G2 in the movement direction Dx is deviated to a side farther away from the indexer block 110 than the first module group G1. Specifically, the second module group G2 is provided in the position where the second module group G2 does not face the transfer part 123 in the width direction DY. In other words, the end G2a of the second module group G2 on the side of the indexer block 110 is located in the same position as the end 123b of the transfer part 123 or an opposite side of the end 123b from the indexer block 110. According to this configuration, the whole module transportation gate GMT can face the main transportation space TS also in the second module group G2.

In the example in FIG. 1, the dry processing module 1A is provided in a last stage position farthest away from the indexer block 110 in the second module group G2. That is to say, the processing module 1 located farthest away from the indexer block 110 in the second module group G2 is the dry processing module 1A. The module transportation gate GMT is provided in a position close to the indexer block 110 in the dry processing module 1A in an arrangement order of the dry processing module 1A of the second module group G2. Thus, the module transportation gate GMT in the last stage position is located closer to the side of the indexer block 110 compared with a case where the wet processing module 1B is provided in the last stage position. Accordingly, the main transporter 80 can transport the substrate W more rapidly between the dry processing module 1A in the last stage position of the second module G2 and the transfer part 123 or the wet processing module 1B.

### Number of Dry Processing Modules and Wet Processing Modules

Herein, a required time for dry processing is longer than that for wet processing. The required time for dry processing may be a supply time of processing gas, or may also be a time from transportation of the substrate W into the dry processing chamber 31 to transportation thereof out of the dry processing chamber 31. The required time for wet processing may be a time from supply start of the processing liquid to drying of the substrate W, or may also be a time from transportation of the substrate W into the wet processing chamber 61 to transportation thereof out of the wet processing chamber 61. As an example, the required time for dry processing is substantially 300 seconds, for example, and the required time for wet processing is substantially 200 seconds, for example.

The number of dry processing modules 1A may be larger than that of wet processing modules 1B. The number of dry processing modules 1A and wet processing modules 1B may be set so that a first value obtained by dividing the required time for dry processing by the number of dry processing modules 1A matches well with a second value obtained by dividing the required time for wet processing by the number of wet processing modules 1B. Herein, a state where the first value and the second value match well with each other indicates that the following condition is satisfied, for example. That is to say, the condition is a condition where a value obtained by dividing a difference between the first value and the second value by the first value is equal to or smaller than a predetermined reference value. The reference value may be equal to or smaller than 0.2, or may also be equal to or smaller than 0.1, for example. In the example described above, a ratio between the number of dry processing modules 1A and the number of wet processing modules 1B can be set to 3:2. For example, each of three towers TW is made up of two dry processing modules 1A, and one tower TW is made up of four wet processing modules 1B. In this case, the number of dry processing modules 1A is six, and the number of wet processing modules 1B is four.

According to this configuration, a standby time for the substrate W to stand by until processing of any one of the dry processing module 1A and the wet processing module 1B is finished can be reduced. Thus, the substrate processing apparatus 100 can perform dry processing and wet processing on the plurality of substrates W with higher throughput.

### Dry Tower

In the example in FIG. 2, the plurality of (herein, two) dry processing modules 1A are stacked in the vertical direction to form one tower TW. The tower TW in FIG. 2 does not include the wet processing module 1B. The tower TW which does not include the wet processing module 1B but includes two or more dry processing modules 1A is also referred to as a dry tower TWA hereinafter.

In the example in FIG. 2, a pipe space PS is provided immediately below the whole load lock chamber 11, the local transportation chamber 21, and the dry processing chamber 31 (that is to say, the dry chamber) in the dry tower TWA. When a space where the dry chamber is provided is referred to as a chamber space, the chamber space and the pipe space PS are alternately provided in the vertical direction in the dry tower TWA. At least a part of a pipe system of the dry processing module 1A is provided in the pipe space PS.

In the example in FIG. 2, at least a part of the first suction pipe 161 and the first pressure adjustment valve 162 are provided in the pipe space PS. Thus, the first pressure adjustment valve 162 is provided close to the load lock chamber 11. Accordingly, the first pressure adjustment valve 162 can adjust pressure in the load lock chamber 11 with higher accuracy. In the example in FIG. 2, at least a part of the second suction pipe 261 and the second pressure adjustment valve 262 are also provided in the pipe space PS. Thus, the second pressure adjustment valve 262 can adjust pressure in the local transportation chamber 21 with higher accuracy. In the example in FIG. 2, at least a part of the third suction pipe 361 and the third pressure adjustment valve 362 are also provided in the pipe space PS. Thus, the third pressure adjustment valve 362 can adjust pressure in the dry processing chamber 31 with higher accuracy.

In the example in FIG. 2, the suction part VP is provided below the dry tower TWA. For example, the dry tower TWA is provided above a step, and the suction part VP is provided below a step (below a floor). The suction part VP is larger than the first pressure adjustment valve 162, for example. However, when such a suction part VP having a large size is provided below the dry tower TWA, a height of each pipe space PS can be reduced. As a result, a height of the dry tower TWA can be reduced.

In the example in FIG. 2, at least a part of the first supply pipe 171 and the first supply valve 172 are provided in the pipe space PS. Thus, the first supply valve 172 is provided close to the load lock chamber 11. Accordingly, the first supply valve 172 can switch supply and stop of gas to the load lock chamber 11 with high responsibility. In the example in FIG. 2, at least a part of the second suction pipe 271 and the second supply valve 272 are also provided in the pipe space PS. Accordingly, the second supply valve 272 can switch supply and stop of gas to the local transportation chamber 21 with high responsibility. In the example in FIG. 2, at least a part of the third supply pipe 371 and the third supply valve 372 are also provided in the pipe space PS. Accordingly, the third supply valve 372 can switch supply and stop of gas to the dry processing chamber 31 with high responsibility.

In the example described above, the wet processing module 1B is not provided to the dry tower TWA. Accordingly, the pipe for the dry processing module 1A and the pipe for the wet processing module 1B are not located together in the dry tower TWA. Thus, a configuration of the pipe in the dry tower TWA can be simplified.

### Suction Part

In the example in FIG. 2, the first suction pipe 161 connected to the load lock chamber 11 and the second suction pipe 261 connected to the local transportation chamber 21 is connected to the common suction part VP. For example, downstream ends of the first suction pipe 161 and the second suction pipe 261 are connected to an upstream end of a common pipe, and a downstream end of the common pipe is connected to the suction part VP. This suction part VP is referred to as a first suction part VP1 hereinafter. In the example in FIG. 2, the first suction part VP1 is not connected to the third suction pipe 361.

When the first suction part VP1 is activated, gas in the load lock chamber 11 is sucked through the first suction pipe 161, and gas in the local transportation chamber 21 is sucked through the second suction pipe 261. That is to say, the first suction part VP1 is used for both the load lock chamber 11 and the local transportation chamber 21. Thus, the number of suction parts VP can be reduced, and manufacturing cost can be reduced.

In the meanwhile, in the example in FIG. 2, the third suction pipe 361 connected to the dry processing chamber 31 is connected to the other suction part VP (referred to as the second suction part VP2 hereinafter) different from the first suction part VP1. In the example in FIG. 2, the second suction part VP2 is not connected to the first suction pipe 161 and the second suction pipe 261. When the second suction part VP2 is activated, gas in the dry processing chamber 31 is sucked through the third suction pipe 361. According to this configuration, gas from the load lock chamber 11 and gas from the local transportation chamber 21 do not flow into the third suction pipe 361 and the second suction part VP2. Thus, the third pressure adjustment valve 362 can adjust pressure in the dry processing chamber 31 without being influenced by these types of gas. That is to say, change of pressure in the dry processing chamber 31 caused by the gas can be avoided. Thus, the third pressure adjustment valve 362 can adjust pressure in the dry processing chamber 31 with higher accuracy. Since a pressure value in the dry processing chamber 31 has influence on a result of dry processing on the substrate W, the dry processing unit 30 can perform dry processing on the substrate W with higher accuracy.

### Wet Tower

In the example in FIG. 3, the plurality of (herein, two) wet processing modules 1B are stacked in the vertical direction to form one tower TW. The tower TW in FIG. 3 does not include the dry processing module 1A. The tower TW which does not include the dry processing module 1A but includes two or more wet processing modules 1B is also referred to as a wet tower TWB hereinafter. Since the dry processing module 1A is not provided to the wet tower TWB, the pipe for the dry processing module 1A and the pipe for the wet processing module 1B are not located together in the wet tower TWB. Thus, a configuration of the pipe in the wet tower TWB can be simplified.

### Transportation System of Dry Processing Module

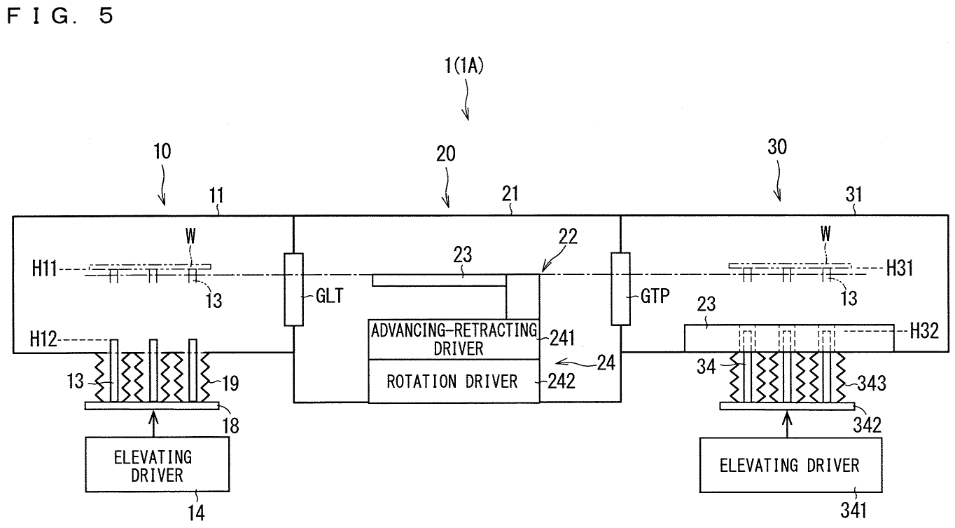

FIG. 5 is a diagram schematically illustrating an example of a transportation configuration of the dry processing module 1A. In the example in FIG. 5, the load lock unit 10 includes the plurality of support pins 13 as an example of the second support member supporting the substrate W and the pin elevating driver 14 as an example of the second elevating driver moving up and down the second support member. The pin elevating driver 14 moves up and down the support pin 13 between a first height position H11 and a second height position H12 described next. The first height position H11 is a position where a distal end of the support pin 13 is located above an upper surface of the hand 23 of the local transporter 22. The substrate W supported by the plurality of support pins 13 located in the first height position H11 is located above the hand 23, and is away from the hand 23. The second height position H12 is a position where the distal end of the support pin 13 is located below the hand 23 of the local transporter 22.

For example, the pin elevating driver 14 includes a drive source such as a motor or an air pump and a power transmission part transmitting drive force of the drive source to the plurality of support pins 13. The power transmission part includes a ball spring mechanism or an air cylinder mechanism, for example. The pin elevating driver 14 is controlled by the controller 90.

In the example in FIG. 5, the hand movement driver 24 of the local transportation unit 20 has a function of moving the substrate W along the horizontal direction but does not have a function of moving up and down the substrate W. That is to say, the local transporter 22 has a role to move the substrate W in the horizontal direction, and the support pin 13 and the pin elevating driver 14 have a role to move up and down the substrate W in transporting the substrate W between the load lock unit 10 and the local transportation unit 20.

In the example in FIG. 5, the hand movement driver 24 includes the advancing-retracting driver 241 and the rotation driver 242. The advancing-retracting driver 241 moves the hand 23 along a horizontal one direction (referred to as an advancing-retracting direction hereinafter). Also with reference to FIG. 1, the hand 23 includes one or more elongated members 23a extending along the advancing-retracting direction, for example. In the example in FIG. 1, the plurality of (specifically, two) elongated members 23a are provided, and base ends of the plurality of elongated members 23a are connected by the connection member 23b. The advancing-retracting driver 241 includes a plurality of arms and a motor adjusting a connection angle of the plurality of arms, for example. The hand 23 is connected to one end of a connector including the plurality of arms, and the other end thereof is connected to the rotation driver 242. When the connection angle of the arm is adjusted, the hand 23 is moved along the advancing-retracting direction. The advancing-retracting driver 241 may include a direct-acting mechanism such as a ball spring mechanism in place of the arm mechanism.

The rotation driver 242 includes a motor, and integrally rotates the hand 23 and the advancing-retracting driver 241 around a rotational axis line along the vertical direction. A direction of the hand 23 can be adjusted by this rotation. Specifically, the rotation driver 242 rotates the hand 23 between a local rotation position and a dry rotation position described next. The local rotation position is a position at which the distal end of the elongated member 23a faces a side of the load lock unit 10, and the dry rotation position is a rotation position at which the distal end of the elongated member 23a faces a side of the dry processing unit 30.

The advancing-retracting driver 241 moves the hand 23 between a load transfer position in the load lock chamber 11 and a position in the local transportation chamber 21 described next along the advancing-retracting direction while the hand 23 is located in the local rotation position. The load transfer position is a position where the substrate W is transferred between the support pin 13 and the local transporter 22. That is to say, the load transfer position is a position where the hand 23 is located immediately below the substrate W while the plurality of support pins 13 support the substrate W at the first height position H11. When the plurality of support pins 13 are moved down from the first height position H11 to the second height position H12 in this state, the substrate W is transferred to the hand 23. In the meanwhile, when the plurality of support pins 13 is moved up from the second height position H12 to the first height position H11 while the hand 23 supports the substrate W at the load transfer position, the plurality of support pins 13 move up the substrate W from the hand 23 of the local transporter 22.

The dry processing unit 30 includes the plurality of elevating pins 34 as an example of the first support member supporting the substrate W and the pin elevating driver 341 as an example of the first elevating driver moving up and down the first support member. The pin elevating driver 341 is controlled by the controller 90, and moves up and down the plurality of elevating pins 34 between a first height position H31 and a second height position H32 described next. The first height position H31 is a position where distal ends of the plurality of elevating pins 34 are located above the hand 23 of the local transporter 22, and the second height position H32 is a position where the distal ends of the plurality of elevating pins 34 are located below the hand 23 of the local transporter 22. As an example herein, the second height position H32 is a position where the distal ends of the plurality of elevating pins 34 are located below the upper surface of the stage 33. The elevating pin 34 and the pin elevating driver 341 are similar to the support pin 13 and the pin elevating driver 14, respectively.

The advancing-retracting driver 241 moves the hand 23 between a position in the local transportation chamber 21 and a dry transfer position in the dry processing chamber 31 described next along the advancing-retracting direction while the hand 23 is located in the dry rotation position. The dry transfer position is a position where the substrate W is transferred between the elevating pin 34 and the local transporter 22. That is to say, the dry transfer position is a position where the hand 23 is located immediately below the substrate W while the plurality of elevating pins 34 support the substrate W at the first height position H31. When the plurality of elevating pins 34 are moved down from the first height position H31 to the second height position H32 in this state, the substrate W is transferred to the hand 23. In the meanwhile, when the plurality of elevating pins 34 are moved up from the second height position H32 to the first height position H31 while the hand 23 supports the substrate W at the dry transfer position, the plurality of elevating pins 34 move up the substrate W from the hand 23 of the local transporter 22.

As described above, in the example in FIG. 5, the load lock unit 10 and the dry processing unit 30 have a function of moving up and down the substrate W. Thus, the local transportation unit 20 needs not have a function of moving up and down the substrate W, and a size of the local transportation unit 20 in the vertical direction can be reduced. That is to say, since the local transporter 22 includes the hand 23 and the hand movement driver 24, the size thereof in the vertical direction gets large. However, when the elevating driver is omitted, the size of the local transportation unit 20 in the vertical direction can be effectively reduced. In the meanwhile, it is sufficient that the load lock unit 10 supports the substrate W, and needs not have a function of moving the substrate W in the horizontal direction. Thus, even when the elevating driver of the substrate W is provided to the load lock unit 10, the size thereof in the vertical direction does not get large so much compared with the local transportation unit 20. The same applies to the dry processing unit 30.

Since the local transporter 22 does not include the elevating driver, a height width of the load transportation gate GLT and a height width of the transportation processing gate GTP can be reduced. Thus, cost of each gate can be reduced. Since the hand 23 needs not be moved up above the elevating pin 34 in the dry processing chamber 31, a height width of the dry processing chamber 31 can also be reduced. Accordingly, a volume of the dry processing chamber 31 can be reduced. Thus, the third pressure adjuster 35 can adjust pressure in the dry processing chamber 31 with higher accuracy.

In the example in FIG. 5, the pin elevating driver 14 is provided to an external space of the load lock chamber 11. In the example in FIG. 5, lower ends of the plurality of support pins 13 are connected to an upper surface of the support plate 18. The support plate 18 has a plate-like shape, for example, and is provided in a posture so that a thickness direction thereof extends along the vertical direction. In the example in FIG. 5, an opening is formed in a bottom part of the load lock chamber 11, and the plurality of support pins 13 are disposed to pass through the opening. In the example in FIG. 5, a bellows 19 is provided between the bottom part of the load lock chamber 11 and the support plate 18. The bellows 19 has a cylindrical accordion-like shape. In the example in FIG. 5, the plurality of bellows 19 surrounding lower parts of the plurality of support pins 13, respectively, are provided. The bellows 19 is deformable in the vertical direction. That is to say, a size of the bellows 19 in the vertical direction is changeable. An upper end peripheral edge of the bellows 19 is connected to a peripheral edge part of the opening of the load lock chamber 11, and a lower end peripheral edge of the bellows 19 is connected to a peripheral edge of the support plate 18.

The pin elevating driver 14 is provided below the support plate 18. The pin elevating driver 14 is connected to the support plate 18, and moves up and down the support plate 18. Accordingly, the plurality of support pins 13 connected to the support plate 18 are moved up and down.

The pin elevating driver 14 is provided outside the load lock chamber 11, thus can be disposed in an atmospheric pressure space (for example, the pipe space PS). Thus, reliability of the pin elevating driver 14 can be increased. As illustrated in FIG. 5, the bellows 19 is provided to the support pin 13 one by one. According to this configuration, a volume of a vacuum part in the load lock chamber 11 can be reduced compared with a structure that a single bellows surrounding the plurality of elevating pins 13 is provided. Thus, the first pressure adjuster 15 can adjust pressure in the load lock chamber 11 with higher accuracy.

In the example in FIG. 5, the pin elevating driver 341 is provided to an external space of the dry processing chamber 31. In the example in FIG. 5, lower ends of the plurality of elevating pins 34 are connected to an upper surface of the support plate 342, and a bellows 343 is provided between a bottom part of the dry processing chamber 31 and the support plate 342. In the example in FIG. 5, the plurality of bellows 343 surrounding lower parts of the plurality of elevating pins 34, respectively, are provided. These are similar to the support plate 18 and the bellows 19, respectively.

Although the substrate processing apparatus 100 is described in detail above, the above description is in all aspects exemplary, and the present disclosure is not limited thereto. The various modification examples described above can be applied in combination as long as they are not contradictory. It is therefore understood that numerous modification examples can be devised without departing from the scope of the disclosure.

For example, in the example described above, the first pressure adjustment valve 162 is provided to the first suction pipe 161. However, the first pressure adjustment valve 162 may be provided to the first supply pipe 171 (corresponding to an example of the first gas pipe). In the similar manner, the second pressure adjustment valve 262 may be provided to the second supply pipe 271 (corresponding to an example of the second gas pipe), and the third pressure adjustment valve 362 may be provided to the third supply pipe 371 (corresponding to an example of the third gas pipe).

The present disclosure includes the following aspects.

A first aspect is a substrate processing apparatus, including: a plurality of dry processing modules each including a load lock unit switching an atmospheric pressure state and a vacuum state, at least one dry processing unit performing dry processing on a substrate in a vacuum state, and a local transporter transporting a substrate between the load lock unit and the dry processing unit in a vacuum state; at least one wet processing module performing wet processing on the substrate; and a main transporter transporting the substrate into and out of the load lock unit in an atmospheric pressure state and transporting a substrate between each of the dry processing modules and the wet processing module.

A second aspect is the substrate processing apparatus according to the first aspect, wherein the main transporter is moved along a longitudinal direction of a main transportation space in the main transportation space having a longitudinal shape, and the load lock unit, the local transporter, and the dry processing unit are arranged along the longitudinal direction in each of the dry processing modules, and the local transporter is provided between the load lock unit and the dry processing unit.

A third aspect is the substrate processing apparatus according to the second aspect, further comprising a transfer part provided on a side of a first end of the main transportation space in the longitudinal direction and to or from which the main transporter transfers the substrate, wherein a first module group is disposed on a first side of the main transportation space in a width direction perpendicular to the longitudinal direction, the first module group includes at least one of the plurality of dry processing modules and the at least one wet processing module arranged along the longitudinal direction, the dry processing unit, the local transporter, and the load lock unit are arranged in this order in a direction from the first end toward a second end of the main transportation space in the longitudinal direction in at least one of the dry processing modules belonging to the first module group, and the wet processing module is provided at a last stage position located farthest away from the transfer part in the first module group.

A fourth aspect is the substrate processing apparatus according to the third aspect, wherein at least a part of the dry processing unit provided in a position closest to the transfer part in the first module group faces the transfer part in the width direction.

A fifth aspect is the substrate processing apparatus according to any one of the second to fourth aspects, further comprising a transfer part provided on a side of a first end of the main transportation space in the longitudinal direction so that the main transporter transfers the substrate, wherein a second module group is provided on a second side of the main transportation space in a width direction perpendicular to the longitudinal direction, the second module group includes at least one of the plurality of dry processing modules arranged along the longitudinal direction, the load lock unit, the local transporter, and the dry processing unit are arranged in this order in a direction from the first end toward a second end of the main transportation space in the longitudinal direction in at least one of the dry processing modules belonging to the second module group, and one of the dry processing modules is provided at a last stage position located farthest away from the transfer part in the second module group.

A sixth aspect is the substrate processing apparatus according to any one of the first to fifth aspects, comprising a dry tower which does not include the wet processing module but includes the two or more dry processing modules stacked in a vertical direction.

A seventh aspect is the substrate processing apparatus according to any one of the first to sixth aspects, wherein the plurality of dry processing module are stacked in a vertical direction to form a dry tower, a chamber space and a pipe space are alternately provided in a vertical direction in the dry tower, the load lock unit includes a load lock chamber provided in the chamber space, the local transporter is provided in a local transportation chamber connected to the load lock chamber through a local transportation gate in the chamber space, the dry processing unit includes a dry processing chamber connected to the local transportation chamber through a transportation processing gate in the chamber space, a first gas pipe is connected to the load lock chamber and a first pressure adjustment valve is provided in the first gas pipe, a second gas pipe is connected to the local transportation chamber and a second pressure adjustment valve is provided in the second gas pipe, a third gas pipe is connected to the dry processing chamber and a third pressure adjustment valve is provided in the third gas pipe, and at least one of the first pressure adjustment valve, the second pressure adjustment valve, and the third pressure adjustment valve is provided in the pipe space.

An eighth aspect is the substrate processing apparatus according to any one of the first to seventh aspects, comprising: a first suction pipe connected to the load lock chamber; a second suction pipe connected to a local transportation chamber where the local transporter is provided; a third suction pipe connected to the dry processing chamber; a first suction part connected to the first suction pipe and the second suction pipe; and a second suction part connected to the third suction pipe.

A ninth aspect is the substrate processing apparatus according to any one of the first to eighth aspects, comprising a wet tower which does not include any of the dry processing modules but includes the two or more wet processing modules stacked in a vertical direction.

A tenth aspect is the substrate processing apparatus according to any one of the first to eighth aspects, wherein a first number of the dry processing units and a second number of the wet processing modules are determined so that a first value obtained by dividing a dry processing time required for the dry processing by the first number and a second value obtained by dividing a wet processing time required for wet processing by the second number match well with each other.

An eleventh aspect is the substrate processing apparatus according to any one of the first to tenth aspects, wherein the dry processing unit includes: a first support member supporting the substrate; and a first elevating driver moving up and down the first support member, the load lock unit includes: a second support member supporting the substrate; and a second elevating driver moving up and down the second support member, and the local transporter includes: a hand supporting or holding the substrate; and a hand movement driver which has a function of moving the hand in a horizontal direction and does not have a function of moving up and down the hand.

According to the first aspect, dry processing and the wet processing can be performed on the substrate with high throughput.

According to the second aspect, the load lock unit, the local transporter, and the dry processing unit are arranged in the longitudinal direction of the main transportation space. Thus, a worker can perform maintenance on each of the load lock unit, the local transporter, and the dry processing unit from a side opposite to the main transporter. Thus, maintenance is easily performed.

According to the third aspect, a transportation distance between the transfer part and the processing module in the last stage position of the first module group can be reduced.

According to the fourth aspect, a transportation distance between the transfer part and the load lock unit of the first module group can be reduced.

According to the fifth aspect, a transportation distance between the transfer part and the processing module in the last stage position of the second module group can be reduced.

According to the sixth aspect, the pipe for the wet processing module and the pipe for the dry processing module are not located together in the dry tower. Thus, the configuration of the dry tower can be simplified.

According to the seventh aspect, pressure in the chamber can be adjusted with high accuracy.

According to the eighth aspect, gas sucked from each of the load lock chamber and the local transportation chamber does not flow into the third suction pipe. Thus, pressure change in the dry processing chamber caused by the gas can be avoided.

According to the ninth aspect, the pipe for the wet processing module and the pipe for the dry processing module are not located together in the wet tower. Thus, the configuration of the wet tower can be simplified.

According to the tenth aspect, dry processing and the wet processing can be performed on the plurality of substrates with high throughput.

According to the eleventh aspect, a size of the local transporter in the vertical direction can be effectively reduced.

What is claimed is:

1. A substrate processing apparatus, comprising:
a plurality of dry processing modules each including a load lock unit switching an atmospheric pressure state and a vacuum state, at least one dry processing unit performing dry processing on a substrate in a vacuum state, and a local transporter transporting a substrate between the load lock unit and the dry processing unit in a vacuum state;
at least one wet processing module performing wet processing on the substrate; and
a main transporter transporting the substrate into and out of the load lock unit in an atmospheric pressure state and transporting a substrate between each of the dry processing modules and the wet processing module.

2. The substrate processing apparatus according to claim 1, wherein
the main transporter is moved along a longitudinal direction of a main transportation space in the main transportation space having a longitudinal shape, and
the load lock unit, the local transporter, and the dry processing unit are arranged along the longitudinal direction in each of the dry processing modules, and the local transporter is provided between the load lock unit and the dry processing unit.

3. The substrate processing apparatus according to claim 2, further comprising
a transfer part provided on a side of a first end of the main transportation space in the longitudinal direction, the main transporter transferring the substrate to or from the transfer part, wherein
a first module group is disposed on a first side of the main transportation space in a width direction perpendicular to the longitudinal direction,
the first module group includes at least one of the plurality of dry processing modules and the at least one wet processing module arranged along the longitudinal direction,
the dry processing unit, the local transporter, and the load lock unit are arranged in this order in a direction from the first end toward a second end of the main transportation space in the longitudinal direction in at least one of the dry processing modules belonging to the first module group, and
the wet processing module is provided at a last stage position located farthest away from the transfer part in the first module group.

4. The substrate processing apparatus according to claim 3, wherein
at least a part of the dry processing unit provided in a position closest to the transfer part in the first module group faces the transfer part in the width direction.

5. The substrate processing apparatus according to claim 2, further comprising
a transfer part provided on a side of a first end of the main transportation space in the longitudinal direction, the main transporter transferring the substrate to or from the transfer part, wherein
a second module group is provided on a second side of the main transportation space in a width direction perpendicular to the longitudinal direction,
the second module group includes at least one of the plurality of dry processing modules arranged along the longitudinal direction,
the load lock unit, the local transporter, and the dry processing unit are arranged in this order in a direction from the first end toward a second end of the main transportation space in the longitudinal direction in at least one of the dry processing modules belonging to the second module group, and
one of the dry processing modules is provided at a last stage position located farthest away from the transfer part in the second module group.

6. The substrate processing apparatus according to claim 1, comprising
a dry tower which does not include the wet processing module but includes the two or more dry processing modules stacked in a vertical direction.

7. The substrate processing apparatus according to claim 1, wherein
the plurality of dry processing modules are stacked in a vertical direction to form a dry tower,
a chamber space and a pipe space are alternately provided in a vertical direction in the dry tower,
the load lock unit includes a load lock chamber provided in the chamber space,
the local transporter is provided in a local transportation chamber connected to the load lock chamber through a local transportation gate in the chamber space,
the dry processing unit includes a dry processing chamber connected to the local transportation chamber through a transportation processing gate in the chamber space,
a first gas pipe is connected to the load lock chamber and a first pressure adjustment valve is provided in the first gas pipe,
a second gas pipe is connected to the local transportation chamber and a second pressure adjustment valve is provided in the second gas pipe,
a third gas pipe is connected to the dry processing chamber and a third pressure adjustment valve is provided in the third gas pipe, and
at least one of the first pressure adjustment valve, the second pressure adjustment valve, and the third pressure adjustment valve is provided in the pipe space.

8. The substrate processing apparatus according to claim 1, comprising:
a first suction pipe connected to the load lock chamber;
a second suction pipe connected to a local transportation chamber where the local transporter is provided;
a third suction pipe connected to the dry processing chamber;
a first suction part connected to the first suction pipe and the second suction pipe; and
a second suction part connected to the third suction pipe.

9. The substrate processing apparatus according to claim 1, comprising
a wet tower which does not include any of the dry processing modules but includes the two or more wet processing modules stacked in a vertical direction.

10. The substrate processing apparatus according to claim 1, wherein
a first number of the dry processing units and a second number of the wet processing modules are determined so that a first value obtained by dividing a dry processing time required for the dry processing by the first number and a second value obtained by dividing a wet processing time required for wet processing by the second number match well with each other.

11. The substrate processing apparatus according to claim 1, wherein
the dry processing unit includes:
a first support member supporting the substrate; and
a first elevating driver moving up and down the first support member,
the load lock unit includes:
a second support member supporting the substrate; and
a second elevating driver moving up and down the second support member, and
the local transporter includes:
a hand supporting or holding the substrate; and
a hand movement driver which has a function of moving the hand in a horizontal direction and does not have a function of moving up and down the hand.
